(19) United States
(12) Patent Application Publication
(10) Pub. No.: US 2026/0231684 A1
(43) Pub. Date: Aug. 6, 2026

(54) MAGNETIC MEMORY

(71) Applicant: Kioxia Corporation, Tokyo (JP)

(72) Inventor: Nobuyuki UMETSU, Kawasaki Kanagawa (JP)

(73) Assignee: Kioxia Corporation, Tokyo (JP)

(21) Appl. No.: 19/273,013

(22) Filed: Jul. 17, 2025

(30) Foreign Application Priority Data
Feb. 6, 2025 (JP) 2025-018590

(51) Int. Cl. H10N 50/10; G11C 11/16; H10B 61/00; H10N 50/80

(52) U.S. Cl. CPC H10N 50/10; G11C 11/161; G11C 11/1673; G11C 11/1675; H10B 61/22; H10N 50/80; G11C 11/1659

(57) ABSTRACT

In a memory, a nonmagnetic-conductive layer connects a second electrode and a third electrode and extends in a first direction. A first magnetic layer is located in a second direction to the nonmagnetic-conductive layer. The first magnetic layer extends in the first direction and includes a first region and a second region, where the first region is located between a first electrode and the nonmagnetic-conductive layer. A second magnetic layer is located between the first region and the first electrode and the magnetization direction thereof is fixed in the second direction. A nonmagnetic-insulating layer is located between the first region and the second magnetic layer. The first electrode is located between the second electrode and the third electrode, at a position overlapping the second or the third electrode. A magnetization direction of the first region is changeable. A magnetization direction of the second region is fixed in the first direction.

### CROSS REFERENCE TO RELATED APPLICATIONS

This application is based upon and claims the benefit of priority from the prior Japanese Patent Application No. 2025-018590, filed on February 6, 2025, the entire contents of which are incorporated herein by reference.

### FIELD

The embodiments of the present invention relate to a magnetic memory.

### BACKGROUND

Magnetic memories (hereinafter, also Magnetic Random Access Memories (MRAMs)) have been developed. Magnetic Tunnel Junction (MTJ) elements are used as storage elements of an MRAM.

A perpendicular magnetized Spin Orbit Torque (SOT)-MRAM needs an external magnetic field or a relatively large current to invert the magnetization direction of each MTJ element.

A domain wall MRAM causes a malfunction of a domain wall motion layer due to a damage of a tunnel barrier layer, or needs a complicated pinned layer structure to confine the domain wall.

### BRIEF DESCRIPTION OF THE DRAWINGS

FIG. 1 is a perspective view illustrating a configuration example of a magnetic memory according to a first embodiment;

FIG. 2 is a plan view illustrating a configuration example of the magnetic memory according to the first embodiment;

FIG. 3 is an equivalent circuit diagram illustrating a configuration example of the magnetic memory according to the first embodiment;

FIG. 4 is a sectional view illustrating a configuration example of one MTJ element according to the first embodiment;

FIG. 5 is a plan view illustrating a configuration example of one MTJ element according to the first embodiment;

FIG. 6 is a diagram illustrating an operation example of the MTJ element according to the first embodiment;

FIG. 7 is a diagram illustrating an operation example of the MTJ element according to the first embodiment;

FIG. 8 is a diagram illustrating an operation example of the MTJ element according to the first embodiment;

FIG. 9 is a diagram illustrating an operation example of the MTJ element according to the first embodiment;

FIG. 10 is a diagram illustrating an operation example of the MTJ element according to the first embodiment;

FIG. 11 is a diagram illustrating an operation example of the MTJ element according to the first embodiment;

FIG. 12 is a sectional view illustrating a configuration example of one MTJ element according to a second embodiment;

FIG. 13 is a plan view illustrating a configuration example of a magnetic memory according to a third embodiment;

FIG. 14 is a plan view illustrating a configuration example of an MTJ element according to a modification of the embodiments described above;

FIG. 15 is a plan view illustrating a configuration example of the MTJ element according to the modification of the embodiments described above;

FIG. 16 is a sectional view illustrating a configuration example of an MTJ element according to another modification of the embodiments described above;

FIG. 17 is another sectional view illustrating a configuration example of the MTJ element according to another modification of the embodiments described above;

FIG. 18 is a plan view illustrating a configuration example of the MTJ element according to another modification of the embodiments described above;

FIG. 19 is another sectional view illustrating a configuration example of the MTJ element according to another modification of the embodiments described above; and

FIG. 20 is another sectional view illustrating a configuration example of the MTJ element according to another modification of the embodiments described above.

### DETAILED DESCRIPTION

In general, according to the embodiment, a magnetic memory according to the present embodiment includes a first electrode, and a second electrode and a third electrode, the second electrode and the third electrode being arranged away from each other in a first direction. A nonmagnetic conductive layer electrically connects the second electrode and the third electrode to each other and extends in the first direction. A first magnetic layer is located in a second direction intersecting with the first direction with respect to the nonmagnetic conductive layer. The first magnetic layer extends in the first direction and includes a first region and a second region arranged along the first direction, where at least a portion of the first region is located between the first electrode and the nonmagnetic conductive layer in the second direction. A second magnetic layer is located between the first region and the first electrode and the magnetization direction thereof is fixed in the second direction. A nonmagnetic insulating layer is located between the first region and the second magnetic layer. The first electrode is located between the second electrode and the third electrode, at a position at least partially overlapping the second electrode, or at a position at least partially overlapping the third electrode as viewed from the second direction. A magnetization direction of the first region is changeable to the second direction. A magnetization direction of the second region is fixed in the first direction. Hereinafter, devices of the present disclosure will be described with reference to the drawings.

The present invention is not limited to the embodiments. In the present specification and the drawings, elements identical to those described in the foregoing drawings are denoted by like reference characters and detailed explanations thereof are omitted as appropriate.

### First embodiment

A magnetic memory according to a first embodiment is a magnetic memory using the Spin-Orbit coupling, that is, an SOT-MRAM that inverts the magnetization direction of a storage layer with a Spin Orbit Torque (SOT). An example in which the present embodiment is applied to an SOT-MRAM is described below. The present embodiment is also applicable to a domain wall MRAM.

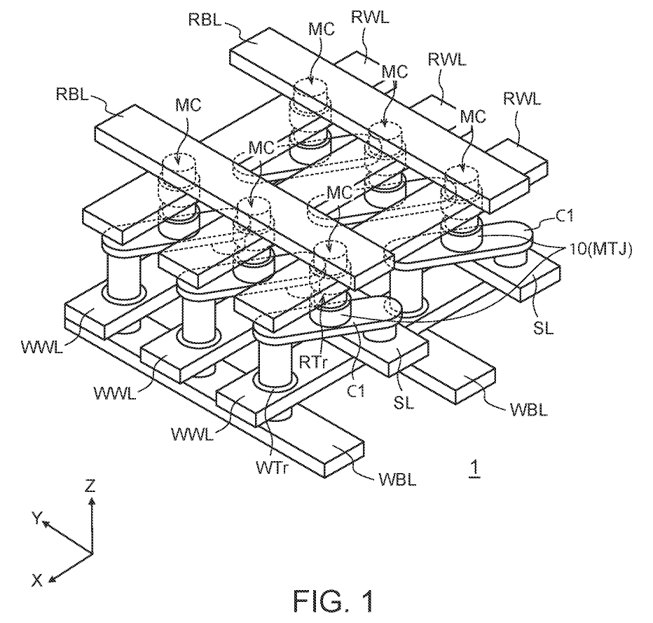

FIG. 1 is a perspective view illustrating a configuration example of a magnetic memory 1 according to the first embodiment. The magnetic memory 1 according to the present embodiment includes write word lines WWL, read word lines RWL, write bit lines WBL, read bit lines RBL, magnetoresistive elements (hereinafter, also MTJ elements) 10, write transistors WTr, and read transistors RTr.

A Z direction is a stacking direction of different types of lines including the write bit lines WBL, the write word lines WWL, source lines SL, the read word lines RWL, and the read bit lines RBL. The Z direction is one example of a second direction. An X direction is any direction intersecting with (for example, orthogonal to) the Z direction in a first plane. A Y direction is a direction intersecting with (for example, orthogonal to) the X direction in the first plane. In the present embodiment, descriptions are made assuming the +Z direction as an upward direction.

The write bit lines WBL, the write word lines WWL, the source lines SL, the MTJ elements 10, the read word lines RWL, and the read bit lines RBL are stacked in this order. The write bit lines WBL, the write word lines WWL, the source lines SL, the read word lines RWL, and the read bit lines RBL are arranged in layers different in the height level in the Z direction, respectively. An interlayer dielectric film (not illustrated) is provided between the write bit lines WBL, the write word lines WWL, the source lines SL, the read word lines RWL, and the read bit lines RBL to electrically separate these lines from each other.

The write bit lines WBL extend in the Y direction and are arrayed in the X direction. In the present embodiment, the write bit lines WBL are arranged in the lowermost layer in the Z direction. Each of the write bit lines WBL causes a current according to data to flow in memory cells MC when the data is to be written to the memory cells MC. For example, the write bit lines WBL are made of a conductive material such as tungsten.

The write word lines WWL extend in the X direction and are arrayed in the Y direction. In the present embodiment, the write word lines WWL are located above the write bit lines WBL in the Z direction. Each of the write word lines WWL brings write transistors WTr to a conduction state (ON) and causes a current flow in conductive layers C1 of associated MTJ elements 10 when data is to be written to memory cells MC. The write word lines WWL are also made of, for example, a conductive material such as tungsten.

The source lines SL extend in the Y direction and are arrayed in the X direction. In the present embodiment, the source lines SL are located above the write word lines WWL in the Z direction. Each of the source lines SL receives a current from an associated MTJ element 10 or causes a current to flow in an associated MTJ element 10 in a write operation and a read operation. The source lines SL are also made of, for example, a conductive material such as tungsten. The source lines SL may be fixed to a common voltage or may be enabled to be individually set at different voltages.

Each of the MTJ elements 10 as magnetoresistive elements is a three-terminal element. An MTJ element 10 is connected between a source or a drain of a write transistor WTr and a source or a drain of a read transistor RTr, and between a source line SL and the source or the drain of the read transistor RTr. An electrode at an upper end of the MTJ element 10 is connected to a source or a drain of the read transistor RTr. Two electrodes at a lower end of the MTJ element 10 are connected to a source or a drain of the write transistor WTr and the source line SL, respectively.

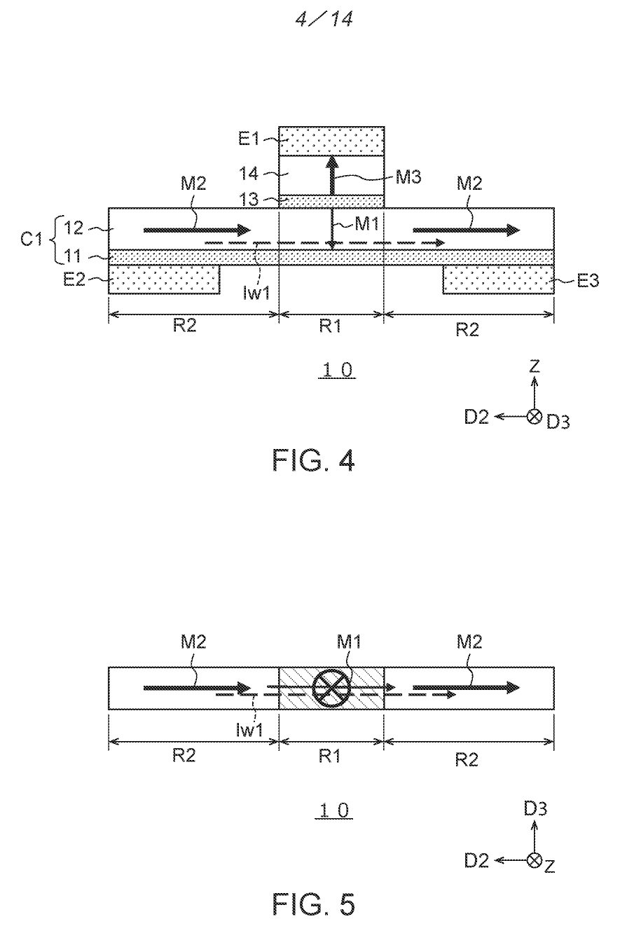

The MTJ elements 10 are located above (in the +Z direction of) the write bit lines WBL, the write word lines WWL, and the source lines SL in the Z direction. The conductive layer C1 of each of the MTJ elements 10 causes a current to flow between a write bit line WBL and a source line SL in a write operation, or causes a current to flow between a read bit line RBL and the source line SL via the MTJ element 10 in a read operation. The conductive layer C1 is constituted of, for example, a laminated body including a nonmagnetic conductive layer (11 in FIG. 4) and a magnetic conductive layer (12 in FIG. 4). A more detailed configuration of the MTJ elements 10 will be described later.

The read word lines RWL extend in the X direction and are arrayed in the Y direction. In the present embodiment, the read word lines RWL are located above the MTJ elements 10 in the Z direction. Each of the read word lines RWL brings read transistors RTr to a conduction state (ON) and causes a current to flow between read bit lines RBL and associated source lines SL via associated MTJ elements 10 when data is to be read from the memory cells MC. The read word lines RWL are made of, for example, a conductive material such as tungsten.

The read bit lines RBL extend in the Y direction and are arrayed in the X direction. In the present embodiment, the read bit lines RBL are located above the read word lines RWL in the Z direction. Each of the read bit lines RBL causes a current to flow in the memory cells MC when data is to be read from the memory cells MC. The read bit lines RBL are made of, for example, a conductive material such as tungsten.

One of the source and the drain of each of the write transistors WTr is connected to a write bit line WBL and the other thereof is connected to a conductive layer C1. The gate of each of the write transistors WTr is connected to a write word line WWL. Accordingly, each of the write transistors WTr is controlled to be turned on or off by a write circuit (not illustrated) that applies a voltage to the associated write word line WWL.

In a write operation, the write transistors WTr are turned on and each cause a current to flow between the associated write bit line WBL and the associated conductive layer C1. This current flows as a write current between the write bit line WBL and the associated source line SL via the conductive layer C1. In the write operation, the read transistors RTr are in an off-state and each interrupt a current between the associated read bit line RBL and the associated MTJ element 10.

One of the source and the drain of each of the read transistors RTr is connected to a read bit line RBL and the other thereof is connected to an upper end of an MTJ element 10. The gate of each of the read transistors RTr is connected to a read word line RWL. Accordingly, each of the read transistors RTr is controlled to be turned on or off by a read circuit (not illustrated) that applies a voltage to the associated read word line RWL.

In a read operation, the read transistors RTr are turned on and each cause a current to flow between the associated read bit line RBL and the associated MTJ element 10. This current flows as a read current between the read bit line RBL and the associated source line SL through the MTJ element 10. In the read operation, the write transistors WTr are in an off-state and each interrupt a current between the write bit line WBL and the conductive layer C1.

As illustrated in FIG. 1, the write transistors WTr and the read transistors RTr are located in different layers in the Z direction and are arranged on sides opposite to each other of the associated MTJ elements 10 in the Z direction. The write transistors WTr are located at the height of the write word lines WWL below the MTJ elements 10. The read transistors RTr are located at the height of the read word lines RWL above the MTJ elements 10. Accordingly, the write transistors WTr and the read transistors RTr can be separately formed and are enabled to have different configurations and different characteristics.

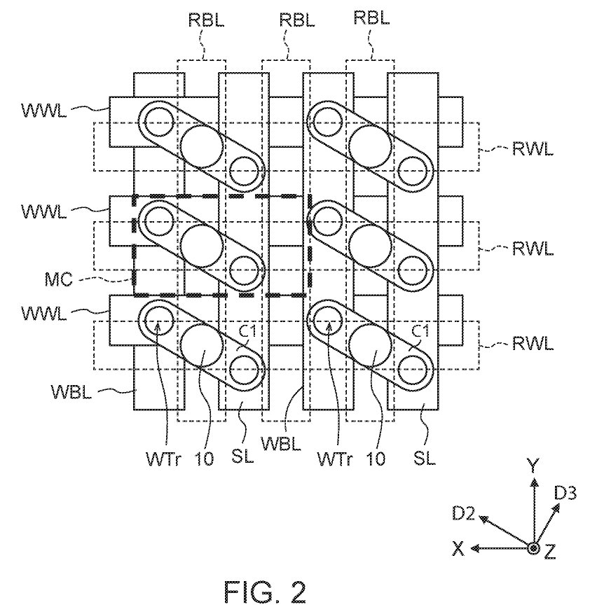

FIG. 2 is a plan view illustrating a configuration example of the magnetic memory 1 according to the first embodiment. FIG. 2 illustrates a plane of the magnetic memory 1 as viewed from the Z direction. The configuration above the conductive layers C1 is represented by broken lines.

In an X-Y plane (a first plane) orthogonal to the Z direction, the write word lines WWL and the read word lines RWL extend substantially in parallel to each other in the X direction and are arrayed in the Y direction. The write bit lines WBL and the read bit lines RBL extend substantially in parallel to each other in the Y direction and are arrayed in the X direction. Therefore, the write word lines WWL and the write bit lines WBL intersect with (for example, are orthogonal to) each other as viewed from the Z direction. The read word lines RWL and the read bit lines RBL intersect with (for example, are orthogonal to) each other as viewed from the Z direction.

The source lines SL extend in the Y direction and are arrayed in the X direction.

The conductive layers C1 are each provided corresponding to each of memory cells MC (each of the MTJ elements 10) and are separated from each other for each of the memory cells MC. The conductive layers C1 extend in a D2 direction inclined with respect to the X and Y directions in the X-Y plane. The D2 direction is a longitudinal direction of each of the conductive layers C1 and is also a direction in which the write current flows through the conductive layer C1. The D2 direction is one example of a first direction. Each of the conductive layers C1 is arranged from a position above the associated write transistor WTr to the position of a contact of the associated source line SL through below the associated MTJ element 10 and the associated read transistor RTr. Therefore, each of the conductive layers C1 is located between the associated write transistor WTr and the associated source line SL with an upper portion of the associated MTJ element 10 as the center. One end of each of the conductive layers C1 is connected to the source or the drain of the associated write transistor WTr and the other end thereof is connected to the associated source line SL.

A planar size of one unit of the memory cell MC is about 6.9 F² (2F×3.45F) and is relatively small. F indicates a feature size where processing using a lithography technique and an etching technique can be performed. With provision of the conductive layers C1 in the inclined direction with respect to the X and Y directions, the contacts of the conductive layers C1 at both ends are arranged in the manner of a hexagonal lattice. Accordingly, the size of the memory cells MC can be reduced.

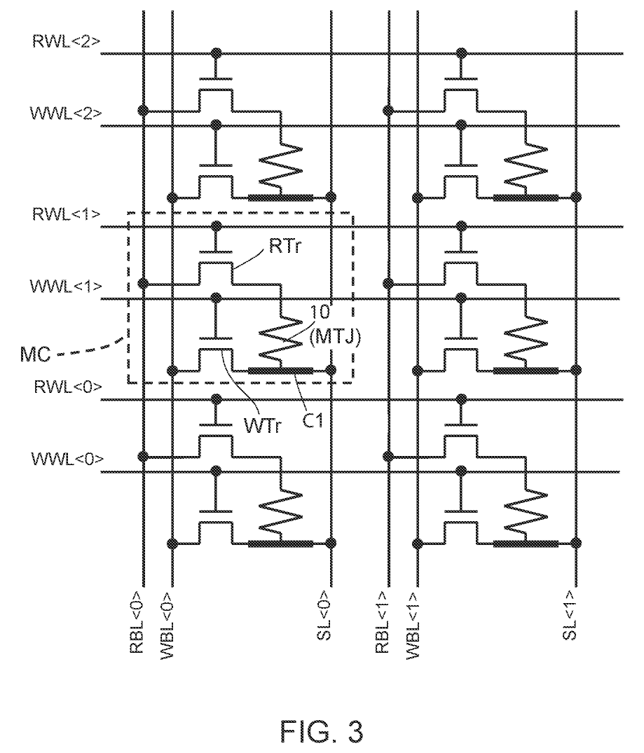

FIG. 3 is an equivalent circuit diagram illustrating a configuration example of the magnetic memory 1 according to the first embodiment. One memory cell MC includes a write transistor WTr, a read transistor RTr, and an MTJ element 10. The conductive layer C1 is included in the MTJ element 10. The connection relation among the write word lines WWL, the read word lines RWL, the write bit lines WBL, the read bit lines RBL, the MTJ elements 10, the write transistors WTr, and the read transistors RTr is as described above.

In a data write operation, a voltage is applied to a selected write word line WWLk (k is any of 0 to i) among a plurality of write word lines WWL<i> (i is an integer) to bring write transistors WTr connected to the selected write word line WWLk to an on-state. Accordingly, a write current is caused to flow to the write transistors WTr and associated conductive layers C1 between write bit lines WBL<i> and source lines SL. The write current controls the magnetization directions of the associated MTJ elements 10 and data is written thereto.

In a data read operation, a voltage is applied to a selected read word line RWLk among a plurality of read word lines RWL<i> to bring read transistors RTr connected to the selected read word line RWLk to an on-state. Accordingly, a read current is caused to flow to the read transistors RTr and associated MTJ elements 10 between read bit lines RBL<i> and source lines SL. At this time, the voltages of the read bit lines RBL<i> become voltages depending on the magnetization directions of the associated MTJ elements 10. By detection of the voltages of the read bit lines RBL<i>, data stored in the associated memory cells MC can be detected.

FIG. 4 is a sectional view illustrating a configuration example of one MTJ element according to the first embodiment. FIG. 5 is a plan view illustrating a configuration example of one MTJ element according to the first embodiment.

The MTJ element 10 includes a first electrode E1, a second electrode E2, a third electrode E3, a nonmagnetic conductive layer 11, a first magnetic layer 12, a nonmagnetic insulating layer 13, and a second magnetic layer 14. The MTJ element 10 is a three-terminal element having the first to third electrodes E1 to E3.

The first electrode E1 is located at an upper part of the MTJ element 10 and allows a current to flow therein in a read operation. The second and third electrodes E2 and E3 are located at a lower part of the MTJ element 10 and allow a write current to flow therein in a write operation. The third electrode E3 connected to the associated source line SL also allows a current in a read operation to flow therein. For example, a conductive metal such as tungsten is used as the first to third electrodes E1 to E3.

The nonmagnetic conductive layer 11 is located in the +Z direction of the second and third electrodes E2 and E3 and electrically connects the second electrode E2 and the third electrode E3 to each other. For example, a nonmagnetic conductive material such as a heavy metal or a topological material that develops the SOT effect is used as the nonmagnetic conductive layer 11. Specifically, W, Ta, Pt, Pd, Hf, Ir, Re, Ag, Au, Bi, Sb, Se, Te, or Mo, or an alloy or a compound including any of these is used. The nonmagnetic conductive layer 11 functions as a so-called SOT layer. The second and third electrodes E2 and E3 are connected to both ends of the nonmagnetic conductive layer 11 and the first magnetic layer 12 in the D2 direction, respectively.

The first magnetic layer 12 is located to be stacked in the +Z direction on the nonmagnetic conductive layer 11. As viewed from the Z direction, the first magnetic layer 12 overlaps the nonmagnetic conductive layer 11 and constitutes the conductive layer C1 along with the nonmagnetic conductive layer 11. For example, a magnetic conductive material such as a 3d transition metal (for example, any of Fe, Co, and Ni), or an alloy including any of these is used as the first magnetic layer 12.

The first magnetic layer 12 is the same continuous member having a shape with the longitudinal direction in the D2 direction. For example, as illustrated in FIG. 5, as viewed from the Z direction, the length of the first magnetic layer 12 in the D2 direction is longer than the length (width) of the first magnetic layer 12 in a D3 direction intersecting with (for example, orthogonal to) the Z direction and the D2 direction. For example, as viewed from the Z direction, the first magnetic layer 12 has a shape such as a substantially rectangular shape or a substantially elliptical shape with the longitudinal direction in the D2 direction. The D3 direction is one example of a third direction.

The first magnetic layer 12 includes a first region R1 and second regions R2 that are adjacent in the D2 direction.

The first region R1 of the first magnetic layer 12 is a region having out-of-plane magnetic anisotropy where a magnetization direction M1 is along the +Z direction or the opposite direction thereof. The first region R1 includes a region of the first magnetic layer 12 where the nonmagnetic insulating layer 13 and the second magnetic layer 14 are located in the +Z direction. The upper surface of the first region R1 is in direct contact with the nonmagnetic insulating layer 13. Accordingly, the first region R1 has out-of-plane magnetic anisotropy. That is, the magnetization direction M1 of the first region R1 is either the +Z or -Z direction. The magnetization direction M1 of the first region R1 can change to the +Z or -Z direction depending on the direction of a write current Iw1 flowing through the nonmagnetic conductive layer 11 or the first magnetic layer 12. That is, the first region R1 functions as an out-of-plane magnetization free layer that has out-of-plane magnetic anisotropy and where the magnetization direction M1 can be inverted by the write current Iw1.

The second regions R2 of the first magnetic layer 12 are regions having in-plane magnetic anisotropy where a magnetization direction M2 is fixed along the D2 direction. The second regions R2 are regions of the first magnetic layer 12 other than the first region R1 and are regions where the nonmagnetic insulating layer 13 and the second magnetic layer 14 are not located in the +Z direction. Since the nonmagnetic insulating layer 13 is not provided on the upper surface of the second regions R2, the second regions R2 of the first magnetic layer 12 have in-plane magnetic anisotropy. That is, the magnetization directions M2 of the second regions R2 are a direction substantially parallel to the X-Y plane. Furthermore, as viewed from the Z direction, each of the second regions R2 has the longitudinal direction in the D2 direction. For example, as viewed from the Z direction, each of the second regions R2 has a shape such as a substantially rectangular shape or a substantially elliptical shape having the longitudinal direction in the D2 direction. Accordingly, the magnetization directions M2 of the second regions R2 can be fixed to either the +D2 or –D2 direction. For example, by temporarily applying an intense external magnetic field at the time of shipment, the magnetization directions M2 of the second regions R2 of a plurality of MTJ elements 10 can be set to the same -D2 direction. The shape of each of the second regions R2 is designed so as to prevent the magnetization direction M2 from being changed by the write current Iw1. Therefore, when the magnetization directions M2 are once set to the same -D2 direction, the magnetization directions M2 are not inverted by the write current Iw1. As a result, each of the second regions R2 functions as an in-plane magnetization fixed layer having the magnetization direction M2 fixed to the -D2 direction.

As described above, the first magnetic layer 12 includes the first region R1 as an out-of-plane magnetization free layer and the second regions R2 as in-plane magnetization fixed layers continuously in the same layer. Two second regions R2 are arranged to sandwich one first region R1 therebetween and are arranged at both sides of the first region R1 to be in contact therewith, respectively. Therefore, a 90° domain wall is formed at a boundary portion between the first region R1 and each of the second regions R2. The 90° domain wall is located in the first magnetic layer 12 along the side surfaces of the nonmagnetic insulating layer 13 and the second magnetic layer 14. As viewed from the Z direction, each of the 90° domain walls may slightly protrude outward from the position of the side surfaces of the nonmagnetic insulating layer 13 and the second magnetic layer 14 as will be described later.

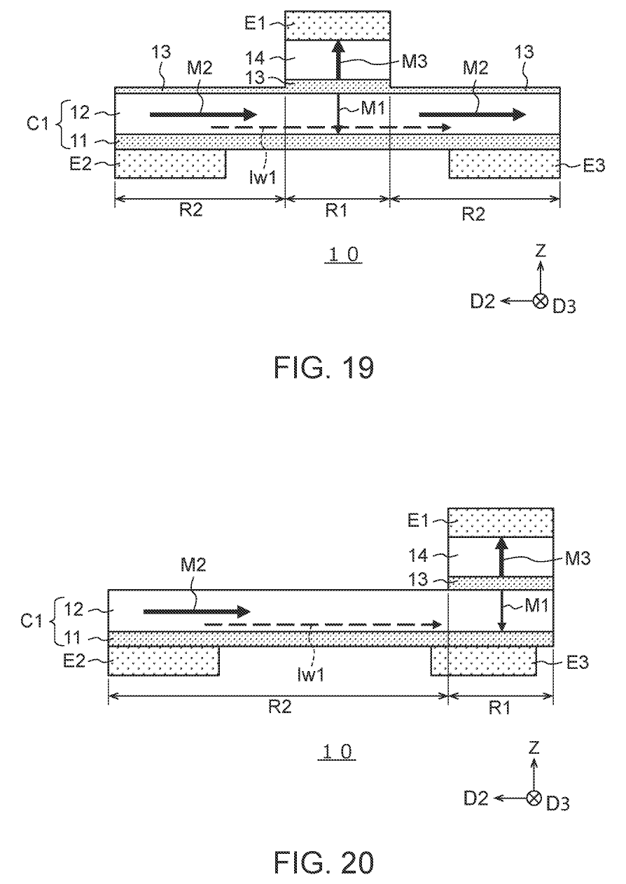

In the present embodiment, the nonmagnetic insulating layer 13 is not located in the +Z direction of the second regions R2. However, there is no problem even when the nonmagnetic insulating layer 13 is located in the +Z direction of the second regions R2 to such an extent that the in-plane magnetic anisotropy of the second regions R2 is not degraded (see FIG. 19).

The nonmagnetic insulating layer 13 is located in the +Z direction of the first region R1 of the first magnetic layer 12. The nonmagnetic insulating layer 13 is arranged at a central portion of the nonmagnetic conductive layer 11 and the first magnetic layer 12 in the D2 direction. For example, a nonmagnetic insulating material such as MgO is used as the nonmagnetic insulating layer 13 of the first magnetic layer 12. The nonmagnetic insulating layer 13 imparts out-of-plane magnetic anisotropy to the first region R1 of the first magnetic layer 12 and the second magnetic layer 14 that are in contact with the nonmagnetic insulating layer 13. The nonmagnetic insulating layer 13 functions as a tunnel barrier film of the MTJ element 10.

The second magnetic layer 14 is located between the nonmagnetic insulating layer 13 and the first electrode E1. The second magnetic layer 14 is located in the +Z direction of the nonmagnetic insulating layer 13. As viewed from the Z direction, the second magnetic layer 14 overlaps the nonmagnetic insulating layer 13. Therefore, the second magnetic layer 14 is arranged at a central portion of the nonmagnetic conductive layer 11 and the first magnetic layer 12 in the D2 direction similarly to the nonmagnetic insulating layer 13. The magnetization direction M3 of the second magnetic layer 14 is fixed to, for example, the +Z direction and the second magnetic layer 14 has out-of-plane magnetic anisotropy. Accordingly, the second magnetic layer 14 functions as an out-of-plane magnetization fixed layer (a reference layer) of the MTJ element 10.

The first electrode E1 is located in the +Z direction of the second magnetic layer 14 and is arranged at a central portion of the nonmagnetic conductive layer 11 and the first magnetic layer 12 in the D2 direction similarly to the second magnetic layer 14 and the nonmagnetic insulating layer 13.

An operation of the magnetic memory 1 according to the present embodiment is described next.

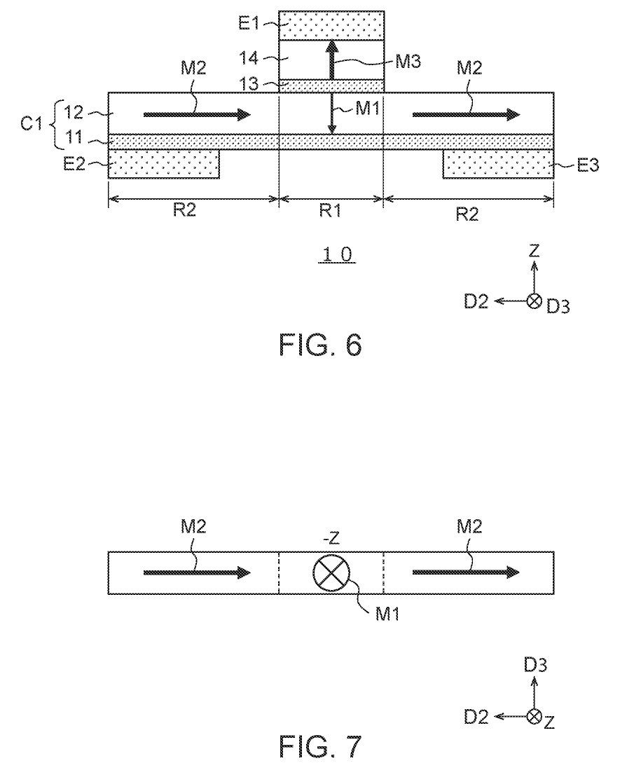

FIGS. 6 to 11 are diagrams illustrating an operation example of the MTJ element according to the first embodiment. FIGS. 6, 8, and 10 illustrate cross sections of the MTJ element 10. FIGS. 7, 9, and 11 illustrate planes of the MTJ element 10 corresponding to FIGS. 6, 8, and 10, respectively.

FIGS. 6 and 7 illustrate magnetization directions of the MTJ element 10 in an initial state. In the initial state, the magnetization direction M1 of the first region R1 faces the -Z direction. The magnetization directions M2 of the second regions R2 are fixed to the -D2 direction. The magnetization direction M3 of the second magnetic layer 14 is fixed to the +Z direction.

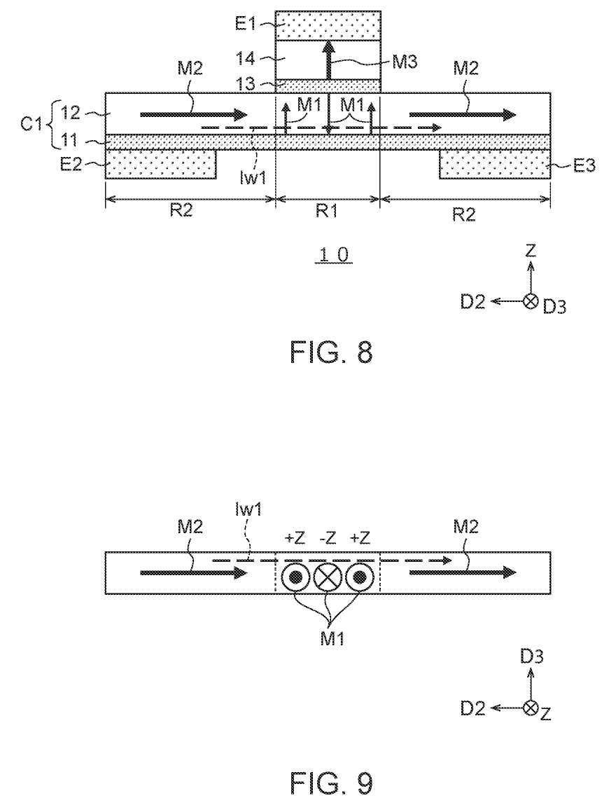

It is assumed that the magnetization direction M1 of the first region R1 is inverted to the +Z direction when the write current Iw1 is caused to flow from the second electrode E2 to the third electrode E3 (in the -D2 direction). In this case, when the write current Iw1 is caused to flow through the first magnetic layer 12 in the -D2 direction as illustrated in FIGS. 8 and 9, with the influence of the SOT, inversion of the magnetization direction M1 is started at boundaries between the first region R1 and the second regions R2. This is because magnetization in the magnetization directions M2 of the second regions R2 generates (leaks) an effective magnetic field in the first region R1 and induces magnetization inversion of the magnetization direction M1 in the first region R1 from the vicinity of each of the boundaries between the first region R1 and the second regions R2 where the magnetization structure is unstable. That is, the magnetization of the second regions R2 provides the first region R1 with the same effect as application of an external magnetic field thereto and induces magnetization inversion. Accordingly, as illustrated in FIGS. 8 and 9, inversion of the magnetization direction M1 of the first region R1 is started from the boundaries between the first region R1 and the second regions R2 and spreads toward the inner part of the first region R1.

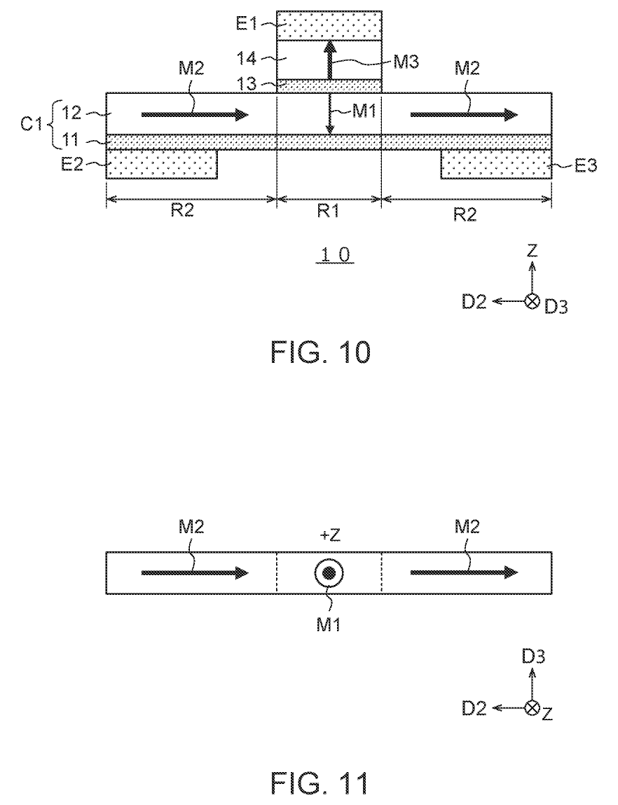

The write current Iw1 may be stopped before the magnetization direction M1 of the first region R1 is completely inverted and in the middle of the inversion. When the inversion of the magnetization direction M1 is started once from the boundaries between the first region R1 and the second regions R2, this inversion operation is continued to some extent and propagates to a central portion of the first region R1. Therefore, even when the write current Iw1 is stopped before the magnetization direction M1 is completely inverted and in the middle of the inversion, the magnetization direction M1 of the first region R1 can be inverted to the -Z direction as illustrated in FIGS. 10 and 11.

Of course, the write current Iw1 may be caused to flow until the inversion of the magnetization direction M1 of the first region R1 is completed. For example, when the length of the first region R1 in the D2 direction is small, the inversion of the magnetization direction M1 is completed in a short time and therefore the write current Iw1 can be stopped after the inversion of the magnetization direction M1 of the first region R1 ends.

In order to invert the magnetization direction M1 of the first region R1 from the +Z direction to the -Z direction, it suffices to cause the write current Iw1 to flow from the third electrode E3 to the second electrode E2 (in the +D2 direction).

According to the present embodiment, the first magnetic layer 12 includes the first region R1 as an out-of-plane magnetization free layer that has out-of-plane magnetic anisotropy and where the magnetization direction M1 can be inverted, and the second regions R2 as in-plane magnetization fixed layers that have in-plane magnetic anisotropy and where the magnetization direction M2 is fixed. The second regions R2 are adjacent to the first region R1 on both sides thereof and are continuous films at the boundaries. Magnetization of the second regions R2 provides the first region R1 with the same effect as application of an external magnetic field thereto and effectively induces magnetization inversion of the first region R1. Accordingly, the magnetization direction M1 of the first region R1 can be inverted with a relatively small write current Iw1 without application of an external magnetic field. The magnetic memory 1 according to the present embodiment eliminates the need of an external magnetic field that is required, for example, for an SOT-MRAM with perpendicular magnetization(type-z) and can decrease the write current relative to that in the SOT-MRAM of the type-z.

The nonmagnetic insulating layer 13 is not arranged on the second regions R2 of the first magnetic layer 12. Alternatively, when the nonmagnetic insulating layer 13 is provided on the second regions R2, the nonmagnetic insulating layer 13 is prevented from disturbing the in-plane magnetic anisotropy of the second regions R2. Accordingly, the nonmagnetic insulating layer 13 on the second regions R2 may be low in the film quality and may include many crystal defects. This enables the second regions R2 of the first magnetic layer 12 to have in-plane magnetic anisotropy and enables the magnetization directions M2 to be fixed by the shape or the like.

On the other hand, in a domain wall MRAM, to cause not only a free layer immediately under a reference layer but also other free layers to have out-of-plane magnetic anisotropy, a tunnel barrier layer is provided also in the free layers other than that immediately under the reference layer. In this case, if the free layers other than that immediately under reference layer lose out-of-plane magnetic anisotropy, the domain wall motion layer becomes non-functional. Therefore, in order to enable the free layers other than that immediately under the reference layer to maintain the out-of-plane magnetic anisotropy, the film thickness of the tunnel barrier layer provided in the free layers other than that immediately under the reference layer needs to be rather large and the film quality also needs to be fine.

In contrast thereto, according to the present embodiment, the second regions R2 of the first magnetic layer 12 can have in-plane magnetic anisotropy and the nonmagnetic insulating layer 13 is not required on the second regions R2. Alternatively, the nonmagnetic insulating layer 13 on the second regions R2 may have such a small film thickness and a deteriorated film quality that do not disturb the in-plane magnetic anisotropy of the second regions R2. Since domain wall generation (confinement) is not required in the magnetic memory 1 according to the present embodiment, the structure is simpler than that of a domain wall MRAM.

In the present embodiment, the magnetization directions M2 of the second regions R2 are fixed by the shape of the second regions R2. However, the method of fixing the magnetization directions M2 of the second regions R2 is not limited thereto.

For example, by forming the first magnetic layer 12 while applying a magnetic field thereto in a formation process of the first magnetic layer 12, the first magnetic layer 12 can be provided with in-plane magnetic anisotropy and the magnetization directions M2 of the second regions R2 can be fixed. In this case, out-of-plane magnetic anisotropy is generated due to interface perpendicular magnetic anisotropy with the nonmagnetic insulating layer 13 in the first region R1 where the nonmagnetic insulating layer 13 is formed and accordingly out-of-plane magnetic isotropy can be maintained.

Furthermore, the magnetization directions M2 of the second regions R2 may be fixed, for example, by layout arrangement of the MTJ elements 10 as illustrated in FIG. 2. In FIG. 2, a plurality of the MTJ elements 10 are positioned to be arranged in the longitudinal direction (the D2 direction) of the conductive layers C1. A plurality of the MTJ elements 10 are arranged within a plane including the D2 direction and the D3 direction, or within a plane including the X direction and the Y direction. With positioning of a plurality of the MTJ elements 10 to be arranged in the longitudinal direction (the D2 direction) of the conductive layers C1, leakage flux is generated to penetrate through the conductive layers C1 of a plurality of memory cells MC in the longitudinal direction. Therefore, the magnetization directions M2 of the second regions R2 of the first magnetic layer 12 can be fixed strongly. As the interval between a plurality of the conductive layers C1 positioned to be arranged in the D2 direction is narrower, the magnetization directions M2 of the second regions R2 can be fixed more strongly. Accordingly, it is preferable that the interval between a plurality of the conductive layers C1 positioned to be arranged in the D2 direction is narrow.

### Second embodiment

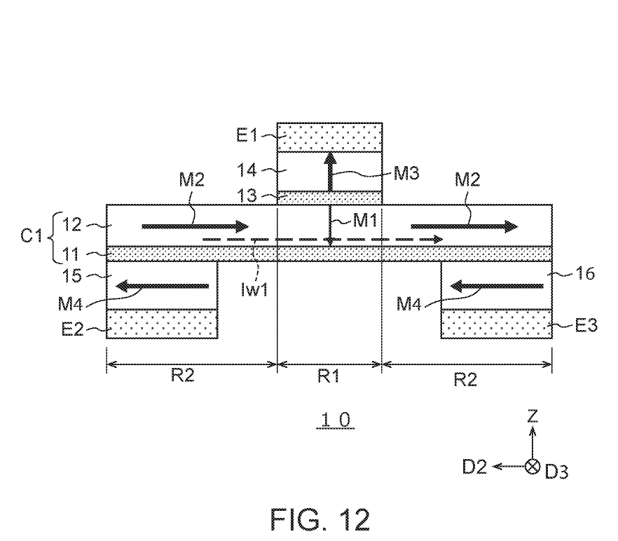

FIG. 12 is a sectional view illustrating a configuration example of one MTJ element according to a second embodiment. The MTJ element according to the second embodiment further includes a third magnetic layer 15 and a fourth magnetic layer 16.

The third magnetic layer 15 is arranged between the second electrode E2 and the nonmagnetic conductive layer 11. The fourth magnetic layer 16 is arranged between the third electrode E3 and the nonmagnetic conductive layer 11. The third and fourth magnetic layers 15 and 16 are both fixed layers that have a magnetization direction M4 opposite to the magnetization directions M2 of the second regions R2 of the first magnetic layer 12 and where the magnetization direction is not changed by the write current Iw1.

The magnetization directions of the third and fourth magnetic layers 15 and 16 are determined so as to close leakage flux generated between the magnetic layers 15 and 16 and the first magnetic layer 12. This enables the magnetization directions M2 of the second regions R2 of the first magnetic layer 12 to be fixed.

The third and fourth magnetic layers 15 and 16 can be the same layer and can be made of the same material. Therefore, the structure of the second embodiment is simpler than that of a domain wall MRAM. Furthermore, since the third and fourth magnetic layers 15 and 16 can be made by the same process, the manufacturing process according to the second embodiment is also simpler than that of a domain wall MRAM.

Other configurations of the second embodiment may be identical to those of the first embodiment. Accordingly, the second embodiment can attain identical effects as those of the first embodiment.

### Third embodiment

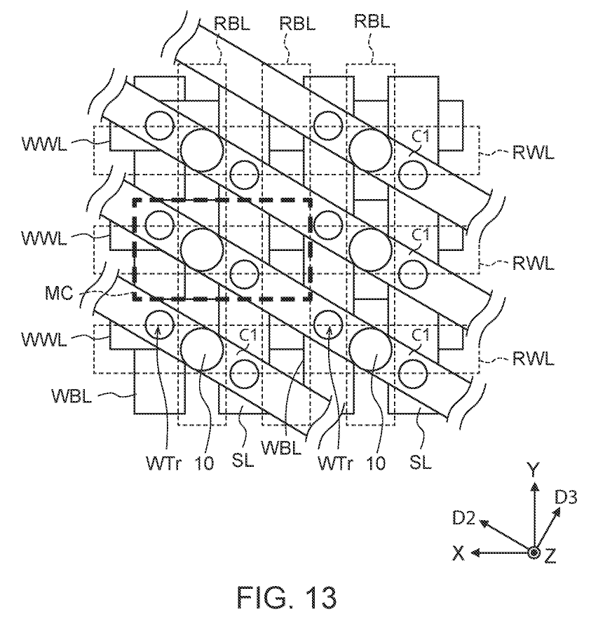

FIG. 13 is a plan view illustrating a configuration example of the magnetic memory 1 according to a third embodiment. FIG. 13 illustrates a plane of the magnetic memory 1 as viewed from the Z direction. The configuration above the conductive layers C1 is represented by broken lines.

In the third embodiment, the conductive layers C1 of a plurality of MTJ elements 10 positioned to be arranged in the D2 direction are continuously connected with each other. In the conductive layers C1, the magnetization directions M2 of the second regions R2 of the first magnetic layer 12 are the same direction (for example, the -D2 direction). Therefore, in a plurality of MTJ elements 10 positioned to be arranged in the D2 direction, the conductive layers C1 can be one continuous conductive layer extending in the D2 direction. With formation of the conductive layers C1 in the D2 direction to be common as a continuous conductive layer, the magnetization directions M2 of the second regions R2 of the first magnetic layer 12 can be fixed much more strongly.

Other configurations of the third embodiment may be identical to those of the first embodiment. Accordingly, the third embodiment can attain identical effects as those of the first embodiment. Further, the third embodiment may be combined with the second embodiment.

### Modifications

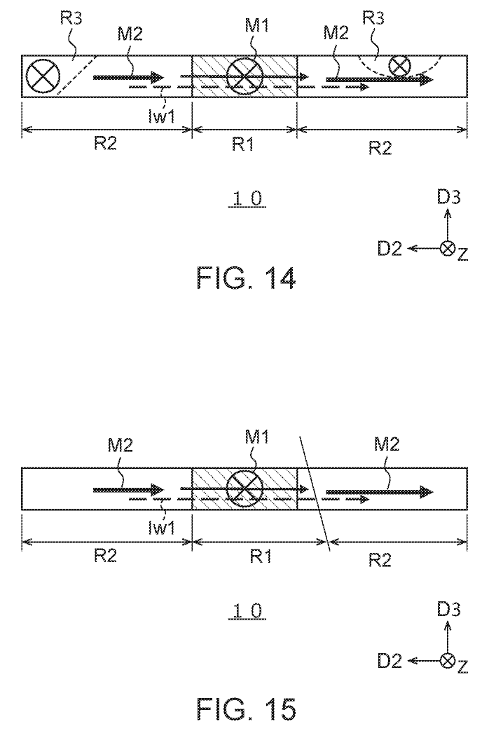

FIGS. 14 and 15 are plan views illustrating configuration examples of an MTJ element according to a modification of the embodiments described above.

In the modification illustrated in FIG. 14, a third region R3 having out-of-plane magnetic anisotropy is included in a part of each of the second regions R2 of the first magnetic layer 12. The magnetization direction of each of the third regions R3 may be either fixed or unfixed. Each of the third regions R3 is not in contact with the boundary between the first region R1 and the associated second region R2. In this case, the effect of an effective magnetic field provided to the first region R1 by the magnetization direction M2 of each of the second regions R2 is not lost. Therefore, there is no problem even when the third region R3 having out-of-plane magnetic anisotropy is included in a part of each of the second regions R2.

In the modification illustrated in FIG. 15, the first region R1 of the first magnetic layer 12 slightly spreads out of the nonmagnetic insulating layer 13 and the second magnetic layer 14 to the second region R2 side as viewed from the Z direction. That is, the boundary between the first region R1 and the second region R2 is slightly shifted outward from the position of the side surfaces of the nonmagnetic insulating layer 13 and the second magnetic layer 14. Also in this case, the valid area of the first region R1 overlapping the nonmagnetic insulating layer 13 and the second magnetic layer 14 as viewed from the Z direction is the same and accordingly the magnetization written to the MTJ element 10 is maintained. Therefore, the effects of the embodiments described above are not lost.

However, if the second region R2 conversely spreads out of the nonmagnetic insulating layer 13 and the second magnetic layer 14 to the first region R1 side as viewed from the Z direction, the valid area of the first region R1 overlapping the nonmagnetic insulating layer 13 and the second magnetic layer 14 becomes smaller and the magnetization written to the MTJ element 10 is reduced. Therefore, it is unfavorable that the boundary between the first region R1 and each of the second regions R2 is shifted to the inner side of the first region R1 from the position of the side surfaces of the nonmagnetic insulating layer 13 and the second magnetic layer 14.

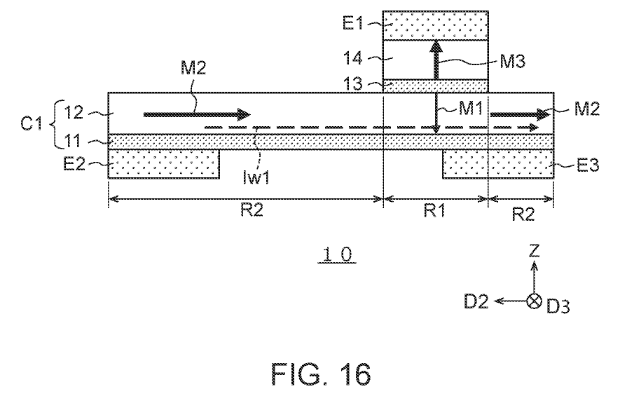

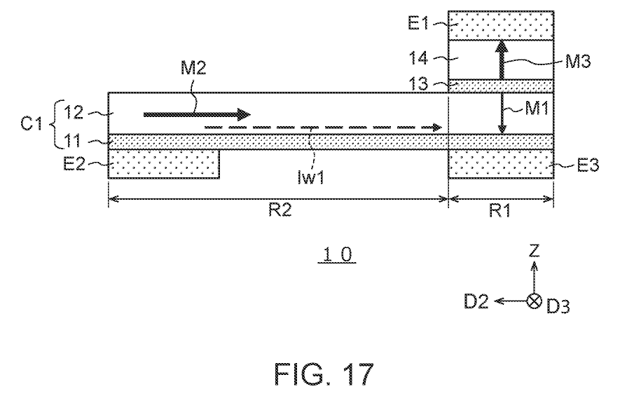

FIGS. 16 and 17 are sectional views illustrating configuration examples of an MTJ element according to another modification of the embodiments described above. As illustrated in FIG. 16, a portion of the first region R1 may overlap the third electrode E3 as viewed from the Z direction. As illustrated in FIG. 17, the entire first region R1 may overlap the third electrode E3 as viewed from the Z direction. Also with these configurations, the effects of the embodiments are not lost.

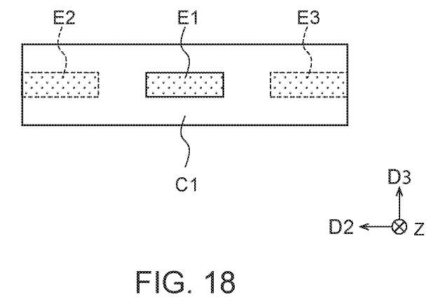

FIG. 18 is a plan view illustrating a configuration example of the MTJ element according to another modification of the embodiments described above. The widths of the first electrode E1, the second electrode E2, and the third electrode E3 in the D3 direction may be narrower than the width of each of the conductive layers C1 in the D3 direction. Also with this configuration, the effects of the embodiments are not lost.

FIG. 19 is another sectional view illustrating a configuration example of the MTJ element according to another modification of the embodiments described above. There is no problem when the nonmagnetic insulating layer 13 is located in the +Z direction of the second regions R2 to such an extent that the in-plane magnetic anisotropy of the second regions R2 is not degraded. For example, in a case where the thickness of the nonmagnetic insulating layer 13 on the upper surface of the second regions R2 is at least smaller than that of the nonmagnetic insulating layer 13 on the upper surface of the first region R1 and the second regions R2 have the in-plane magnetic anisotropy, the nonmagnetic insulating layer 13 may be located on the upper surface of the second regions R2. Alternatively, for example, in a case where crystal defects included in the nonmagnetic insulating layer 13 on the upper surface of the second regions R2 are at least more than those included in the nonmagnetic insulating layer 13 on the upper surface of the first region R1 and the second regions R2 have in-plane magnetic anisotropy, the nonmagnetic insulating layer 13 may be located on the upper surface of the second regions R2.

FIG. 20 is another sectional view illustrating a configuration example of the MTJ element according to another modification of the embodiments described above. In this modification, the third electrode E3 is shifted toward the second electrode E2 as compared to the configuration example illustrated in FIG. 17, and portions of the nonmagnetic conductive layer 11, the first magnetic layer 12, the nonmagnetic insulating layer 13, the second magnetic layer 14, and the first electrode E1 are protruded from an end part of the third electrode E3 on the opposite side to the second electrode E2. In this case, since no current flows in the protruded portions, the magnetization inversion efficiency is decreased to some extent. However, for example, when the protruded portions are equal to or smaller than a half of the width of the third electrode E3 in the D2 direction, the decrease in the magnetization inversion efficiency is in an acceptable range. Therefore, also with this configuration, the effects of the embodiments are not lost.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A magnetic memory comprising:
a first electrode;
a second electrode and a third electrode, the second electrode and the third electrode being arranged away from each other in a first direction;
a nonmagnetic conductive layer electrically connecting the second electrode and the third electrode to each other and extending in the first direction;
a first magnetic layer located in a second direction intersecting with the first direction with respect to the nonmagnetic conductive layer, the first magnetic layer extending in the first direction and comprising a first region and a second region arranged along the first direction, where at least a portion of the first region is located between the first electrode and the nonmagnetic conductive layer in the second direction and at least a portion of the second region overlaps the second electrode in the second direction;
a second magnetic layer located between the first region and the first electrode; and
a nonmagnetic insulating layer located between the first region and the second magnetic layer, wherein
the first electrode is located between the second electrode and the third electrode, at a position at least partially overlapping the second electrode, or at a position at least partially overlapping the third electrode as viewed from the second direction, and
a thickness of the nonmagnetic insulating layer at a portion overlapping the second region as viewed from the second direction is smaller than that of a portion thereof overlapping the first region.

2. The memory of claim 1, wherein the nonmagnetic insulating layer includes more crystal defects in a portion overlapping the second region as viewed from the second direction than those in a portion overlapping the first region.

3. The memory of claim 1, wherein the first magnetic layer has a shape having a longitudinal direction in a direction in which a write current flows through the nonmagnetic conductive layer or the first magnetic layer as viewed from the second direction.

4. The memory of claim 1, wherein
the first direction is a direction in which a write current flows through the nonmagnetic conductive layer or the first magnetic layer, and
a length of the first magnetic layer in the first direction is longer than that of the first magnetic layer in a third direction intersecting with the first direction and the second direction as viewed from the second direction.

5. The memory of claim 1, wherein
the first magnetic layer comprises a plurality of the second regions, and
the second regions are located on both sides of the first region in the first direction.

6. The memory of claim 1, wherein
the second electrode and the third electrode are connected to both ends of the nonmagnetic conductive layer and the first magnetic layer in the first direction, respectively, and
the nonmagnetic insulating layer, the second magnetic layer, and the first electrode are positioned at a central portion of the nonmagnetic conductive layer and the first magnetic layer.

7. The memory of claim 1, further comprising:
a third magnetic layer located between the second electrode and the nonmagnetic conductive layer; and
a fourth magnetic layer located between the third electrode and the nonmagnetic conductive layer.

8. The memory of claim 1, wherein at least a portion of the second region overlaps the second electrode in the second direction.

9. The memory of claim 1, comprising:
a source line connected to the third electrode;
a first read line connected to the second electrode; and
a second read line connected to the first electrode, wherein
the first direction is a direction inclined with respect to the source line, the first read line, or the second read line.

10. The memory of claim 1, comprising at least a first magnetoresistive element and a second magnetoresistive element, wherein
each of the first magnetoresistive element and the second magnetoresistive element comprises the first electrode, the second electrode, the third electrode, the nonmagnetic conductive layer, the first magnetic layer, the nonmagnetic insulating layer, and the second magnetic layer, and
the first magnetoresistive element and the second magnetoresistive element are arranged in a plane comprising a third direction intersecting with the first direction and the second direction.

11. The memory of claim 10, wherein the nonmagnetic conductive layer and the first magnetic layer are separated for each of the magnetoresistive elements as viewed from the second direction.

12. A magnetic memory comprising:
a first electrode;
a second electrode and a third electrode, the second electrode and the third electrode being arranged away from each other in a first direction;
a nonmagnetic conductive layer electrically connecting the second electrode and the third electrode to each other and extending in the first direction;
a first magnetic layer located in a second direction intersecting with the first direction with respect to the nonmagnetic conductive layer, the first magnetic layer extending in the first direction and comprising a first region and a second region arranged along the first direction, where at least a portion of the first region is located between the first electrode and the nonmagnetic conductive layer in the second direction;
a second magnetic layer located between the first region and the first electrode and having a magnetization direction fixed in the second direction; and
a nonmagnetic insulating layer located between the first region and the second magnetic layer, wherein
the first electrode is located between the second electrode and the third electrode, at a position at least partially overlapping the second electrode, or at a position at least partially overlapping the third electrode as viewed from the second direction,
a magnetization direction of the first region is changeable to the second direction, and
a magnetization direction of the second region is fixed in the first direction.

13. The memory of claim 12, wherein the nonmagnetic insulating layer is not located in the second direction of the second region.

14. The memory of claim 12, wherein the nonmagnetic insulating layer includes more crystal defects in a portion overlapping the second region as viewed from the second direction than those in a portion overlapping the first region.

15. The memory of claim 12, wherein the first magnetic layer has a shape having a longitudinal direction in a direction in which a write current flows through the nonmagnetic conductive layer or the first magnetic layer as viewed from the second direction.

16. The memory of claim 12, wherein
the first magnetic layer comprises a plurality of the second regions, and
the second regions are located on both sides of the first region in the first direction.

17. The memory of claim 12, wherein
the first region has a magnetization direction changed according to a direction of a write current flowing through the nonmagnetic conductive layer or the first magnetic layer, and
the second region has a magnetization direction unchanged by the write current.

18. The memory of claim 12, wherein
the second electrode and the third electrode are respectively connected to both ends of the nonmagnetic conductive layer and the first magnetic layer in the first direction, and
the nonmagnetic insulating layer, the second magnetic layer, and the first electrode are positioned at a central portion of the nonmagnetic conductive layer and the first magnetic layer.

19. The memory of claim 12, further comprising:
a third magnetic layer located between the second electrode and the nonmagnetic conductive layer; and
a fourth magnetic layer located between the third electrode and the nonmagnetic conductive layer, wherein
the third and fourth magnetic layers have a magnetization direction opposite to a magnetization direction in the second region, and has a magnetization direction unchanged by a write current flowing through the nonmagnetic conductive layer or the first magnetic layer.

20. A magnetic memory comprising a first magnetoresistive element and a second magnetoresistive element, wherein
each of the first magnetoresistive element and the second magnetoresistive element comprises:
a first electrode;
a second electrode and a third electrode arranged away from each other in a first direction;
a nonmagnetic conductive layer electrically connecting the second electrode and the third electrode to each other and extending in the first direction;
a first magnetic layer located in a second direction intersecting with the first direction with respect to the nonmagnetic conductive layer, the first magnetic layer extending in the first direction and comprising a first region and a second region arranged along the first direction, where at least a portion of the first region is located between the first electrode and the nonmagnetic conductive layer in the second direction;
a second magnetic layer located between the first region and the first electrode; and
a nonmagnetic insulating layer located between the first region and the second magnetic layer,
the first electrode is located between the second electrode and the third electrode, at a position at least partially overlapping the second electrode, or at a position at least partially overlapping the third electrode as viewed from the second direction,
the first magnetoresistive element and the second magnetoresistive element are arranged in a plane comprising a third direction intersecting with the first direction and the second direction, and
the nonmagnetic conductive layer of the first magnetoresistive element is connected and continuous with the nonmagnetic conductive layer of the second magnetoresistive element, and the first magnetic layer of the first magnetoresistive element is connected and continuous with the first magnetic layer of the second magnetoresistive element, as viewed from the second direction.
